(19) United States
(12) Patent Application Publication
(10) Pub. No.: US 2024/0105526 A1
(43) Pub. Date: Mar. 28, 2024

(54) ELECTRONIC DEVICE, ELECTRONIC STRUCTURE AND METHOD OF MANUFACTURING THE SAME

(71) Applicant: NANYA TECHNOLOGY CORPORATION, NEW TAIPEI CITY (TW)

(72) Inventor: YI-JEN LO, NEW TAIPEI CITY (TW)

(21) Appl. No.: 17/954,752

(22) Filed: Sep. 28, 2022

(51) Int. Cl. H01L 21/66; H01L 23/00; H01L 25/065

(52) U.S. Cl. CPC H01L 22/32; H01L 24/08; H01L 24/80; H01L 25/0657; H01L 2224/08123; H01L 2224/80895; H01L 2224/80896

(57) ABSTRACT

An electronic device, an electronic structure and a manufacturing method are provided. The electronic device includes a substrate, a conductive structure and at least one external connector. The conductive structure is disposed on the substrate and includes a test pad configured to be contacted by a probe during a testing process. The external connector is electrically connected to the conductive structure and is exposed from a surface of the electronic device for an external electrical connection. A vertical projection of the at least one external connector overlaps a vertical projection of the test pad.

### TECHNICAL FIELD

The present disclosure relates to an electronic device, an electronic structure and a method of manufacturing the same, and more particularly, to an electronic device including a test pad, and a method of manufacturing the same.

### DISCUSSION OF THE BACKGROUND

Semiconductor structures are used in a variety of electronic applications, and the dimensions of semiconductor structures are continuously being scaled down to meet the current application requirements. However, a variety of issues arise during the scaling-down process and impact the final electrical characteristics, quality, cost and yield.

This Discussion of the Background section is provided for background information only. The statements in this Discussion of the Background are not an admission that the subject matter disclosed herein constitutes prior art with respect to the present disclosure, and no part of this Discussion of the Background may be used as an admission that any part of this application constitutes prior art with respect to the present disclosure.

### SUMMARY

One aspect of the present disclosure provides an electronic device including a substrate, a conductive structure and at least one external connector. The conductive structure is disposed on the substrate and includes a test pad configured to be contacted by a probe during a testing process. The external connector is electrically connected to the conductive structure and is exposed from a surface of the electronic device for an external electrical connection. A vertical projection of the at least one external connector overlaps a vertical projection of the test pad.

Another aspect of the present disclosure provides an electronic structure including a first substrate, a first conductive structure and a second conductive structure. The first conductive structure is disposed over the first substrate, and includes a first test pad configured to be contacted by a probe during a testing process. The second conductive structure is disposed under the first substrate, and includes a second test pad configured to be contacted by a probe during a testing process. An electrical path between the first conductive structure and the second conductive structure is located between the first test pad and the second test pad.

Another aspect of the present disclosure provides a manufacturing method. The manufacturing method includes forming a first conductive via in a first substrate and a first conductive structure on the first substrate, wherein the first conductive via is electrically connected to the first conductive structure, the first conductive structure defines a first opening to expose a first test pad thereof, and the first conductive via is disposed under the first test pad; testing the first test pad; and thinning the first substrate to expose the first conductive via.

The foregoing has outlined rather broadly the features and technical advantages of the present disclosure in order that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

A more complete understanding of the present disclosure may be derived by referring to the detailed description and claims when considered in connection with the Figures, where like reference numbers refer to similar elements throughout the Figures, and:

FIG. 1 is a schematic cross-sectional view of an electronic structure in accordance with some embodiments of the present disclosure.

FIG. 2 is an enlarged cross-sectional view of the first portion of the electronic structure of FIG. 1.

FIG. 3 is an enlarged cross-sectional view of the second portion of the electronic structure of FIG. 1.

FIG. 4 is an enlarged cross-sectional view of the third portion of the electronic structure of FIG. 1.

FIG. 5 is an enlarged cross-sectional view of the fourth portion of the electronic structure of FIG. 1.

FIG. 6 is a partially enlarged top view of the electronic structure of FIG. 1.

FIG. 7 is a schematic cross-sectional view of an electronic structure in accordance with some embodiments of the present disclosure.

FIG. 8 is an enlarged cross-sectional view of the first portion of the electronic structure of FIG. 7.

FIG. 9 is an enlarged cross-sectional view of the second portion of the electronic structure of FIG. 7.

FIG. 10 is an enlarged cross-sectional view of the third portion of the electronic structure of FIG. 7.

FIG. 11 is an enlarged cross-sectional view of the fourth portion of the electronic structure of FIG. 7.

FIG. 12 is a schematic cross-sectional view of an electronic structure in accordance with some embodiments of the present disclosure.

FIG. 13 is a partially enlarged top view of the electronic structure of FIG. 12.

FIG. 14 is a schematic cross-sectional view of an electronic structure in accordance with some embodiments of the present disclosure.

FIG. 15 is a partially enlarged top view of the electronic structure of FIG. 14.

FIG. 16 to FIG. 25 illustrate various stages of a method of manufacturing an electronic structure, in accordance with some embodiments of the present disclosure.

FIG. 26 is a flowchart of a method of manufacturing an electronic structure, in accordance with some embodiments of the present disclosure.

### DETAILED DESCRIPTION

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that, although the terms first, second, third, etc., may be used herein to describe various elements, components, regions, layers or sections, these elements, components, regions, layers or sections are not limited by these terms. Rather, these terms are merely used to distinguish one element, component, region, layer or section from another region, layer or section. Thus, a first element, component, region, layer or section discussed below could be termed a second element, component, region, layer or section without departing from the teachings of the present inventive concept.

The terminology used herein is for the purpose of describing particular example embodiments only and is not intended to be limited to the present inventive concept. As used herein, the singular forms “a,” “an” and “the” are intended to include the plural forms as well, unless the context clearly indicates otherwise. It shall be further understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

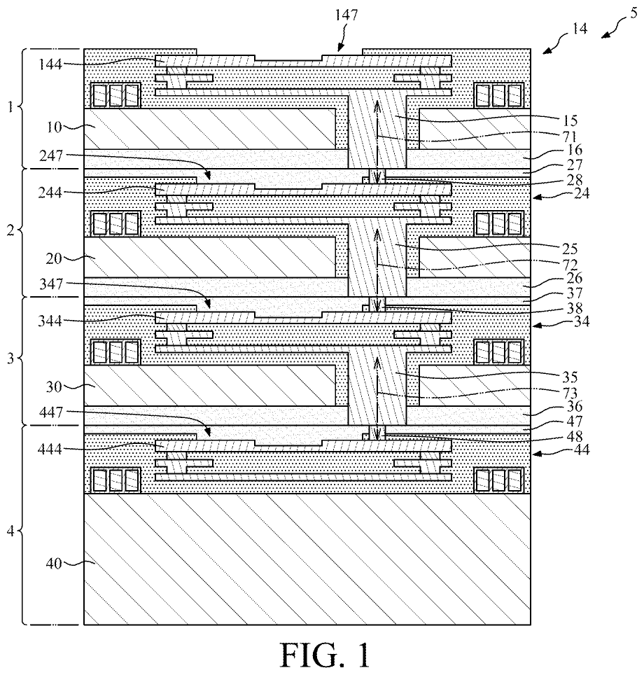

FIG. 1 is a schematic cross-sectional view of an electronic structure 5 in accordance with some embodiments of the present disclosure. In some embodiments, the electronic structure 1 may be a semiconductor structure or a semiconductor device that includes a plurality of electronic devices stacked on one another. Thus, the electronic structure 1 may be a stacked structure that includes a plurality stacked memory devices (e.g., dynamic random access memories (DRAMs)). For example, the electronic structure 1 may be a high bandwidth memory (HBM). In some embodiments, the electronic structure 1 may include a first portion (e.g., a first electronic device 1), a second portion (e.g., a second electronic device 2), a third portion (e.g., a third electronic device 3) and a fourth portion (e.g., a fourth electronic device 4). The third portion (e.g., the third electronic device 3) is stacked on and connected to the fourth portion (e.g., the fourth electronic device 4). The second portion (e.g., a second electronic device 2) is stacked on and connected to the third portion (e.g., the third electronic device 3). The first portion (e.g., the first electronic device 1) is stacked on and connected to the second portion (e.g., a second electronic device 2).

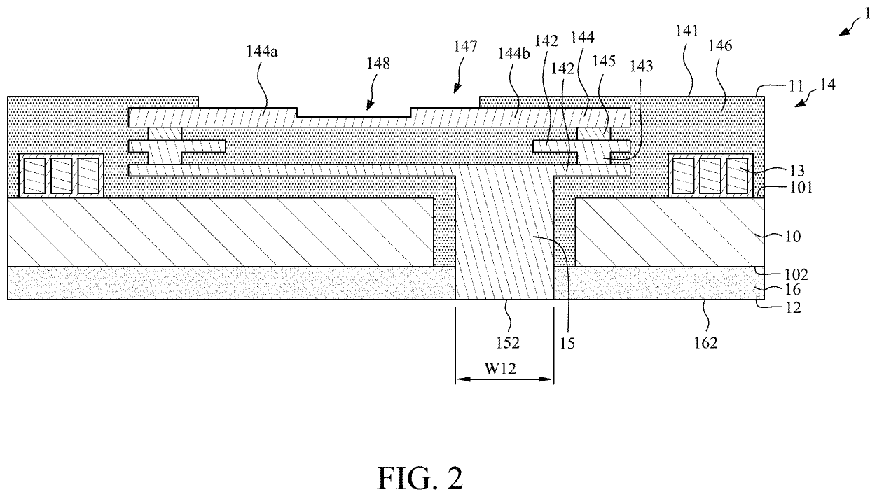

FIG. 2 is an enlarged cross-sectional view of the first portion of the electronic structure 5 of FIG. 1. The first portion may be a first electronic device 1. The first electronic device 1 may be or include a portion of an integrated circuit (IC) chip that includes various passive and active microelectronic devices, such as resistors, capacitors, inductors, diodes, p-type field-effect transistors (pFETs), n-type field-effect transistors (nFETs), metal-oxide semiconductor field-effect transistors (MOSFETs), complementary metal-oxide semiconductor (CMOS) transistors, bipolar junction transistors (BJTs), laterally-diffused MOS (LDMOS) transistors, high-voltage transistors, high-frequency transistors, fin field-effect transistors (FinFETs), other suitable IC components, or combinations thereof.

The first electronic device 1 may have a first surface 11 (e.g., a top surface) and a second surface 12 (e.g., a bottom surface) opposite to the first surface 11. The first electronic device 1 may include a first substrate 10, a capacitor cell 13, a first conductive structure 14, a first bottom passivation layer 16 and at least one first external connector (e.g., a first conductive via 15).

In some embodiments, the first substrate 10 (e.g., a semiconductor substrate) may have a first surface 101 (e.g., a top surface) and a second surface 102 (e.g., a bottom surface) opposite to the first surface 101. The first substrate 10 may include, for example, silicon (Si), doped silicon, germanium (Ge), silicon germanium (SiGe), silicon carbide (SiC), silicon germanium carbide (SiGeC), gallium (Ga), gallium arsenide (GaAs), indium (In), indium arsenide (InAs), indium phosphide (InP) or other IV-IV, III-V or II-VI semiconductor materials. In some other embodiments, the first substrate 10 may include a semiconductor-on-insulator substrate, such as a silicon-on-insulator (SOI) substrate, a silicon germanium-on-insulator (SGOI) substrate, or a germanium-on-insulator (GOI) substrate.

Depending on the IC fabrication stage, the first substrate 10 may include various material layers (e.g., dielectric layers, semiconductor layers, and/or conductive layers) configured to form IC features (e.g., doped regions, isolation features, gate features, source/drain features, interconnect features, other features, or combinations thereof).

The capacitor cell 13 may be disposed on or disposed over the first surface 101 of the first substrate 10. In some embodiments, the capacitor cell 13 may be embedded in the first substrate 10.

The first conductive structure 14 may be disposed on or disposed over the first surface 101 of the first substrate 10, may have a first surface 141 (e.g., a top surface). The first surface 141 of the first conductive structure 14 may be the first surface 11 of the first electronic device 1. The first conductive structure 14 may include a plurality of patterned metal layers 142, a plurality of inner vias 143, a first test pad 144, at least one inner via 145 and a dielectric structure 146. The dielectric structure 146 may include one or more dielectric layers. The patterned metal layers 142, the inner vias 143, the first test pad 144, the inner via 145 and the capacitor cell 13 may be embedded in or may be covered by the dielectric structure 146.

The patterned metal layers 142 may be patterned circuit layers 142, and may be electrically connected to each other by the inner vias 143. The patterned metal layers 142 may be a back-end-of-line (BEOL) or a front-end-of-line (FEOL). A material of the patterned metal layers 142 and the inner vias 143 may include copper (Cu). The first test pad 144 may be electrically connected to the patterned metal layers 142 through the inner via 145. A material of the first test pad 144 may include aluminum (Al), a material of the inner via 145 may include tungsten (W).

The first test pad 144 may be configured to be contacted by a probe during a testing process. The first test pad 144 may include a first portion 144a and a second portion 144b. The dielectric structure 146 may define a first opening 147 to expose the first portion 144a of the first test pad 144. The first portion 144a may be configured to be contacted by the probe during the testing process. Thus, the first portion of 144a the first test pad 144 may have a probe mark 148 thereon after the testing process. The probe mark 148 may be a recess portion recessed from a top surface of the first test pad 144. In addition, the second portion 144b may be covered by the dielectric structure 146. That is, the size of the first opening 147 may be less than the size of the first test pad 144.

The first bottom passivation layer 16 may be disposed on the second surface 102 of the first substrate 10 and may surround the first external connector (e.g., a first conductive via 15). The first bottom passivation layer 16 may have a second surface 162 (e.g., a bottom surface). The second surface 162 of the first bottom passivation layer 16 may be the second surface 12 of the first electronic device 1. A material of the first bottom passivation layer 16 may include oxide material or nitride material, such as silicon nitride (Si₃N₄, or SiN), silicon dioxide (SiO₂), silicon oxynitride (N₂OSi₂), silicon nitride oxide (SiON), tantalum pentoxide (Ta₂O₅), aluminum oxide (Al₂O₃), strontium bismuth tantalum oxide (SrBi₂Ta₂O₉, SBT), barium strontium titanate oxide (BaSrTiO₃, BST), or a combination thereof.

The first external connector may include a first conductive via 15. The first conductive via 15 may be electrically connected to the patterned metal layers 142 of the first conductive structure 14, and may be exposed from the second surface 12 of the first electronic device 1 for an external electrical connection. A material of the first conductive via 15 may be copper. The first conductive via 15 may extend through the first substrate 10, and may be disposed right under the patterned metal layers 142 of the first conductive structure 14.

As shown in FIG. 1, a length of the first conductive via 15 may be greater than a thickness of the first substrate 10. Thus, the first conductive via 15 may extend beyond the second surface 102 of the first substrate 10. In addition, the first conductive via 15 may further extend through the first bottom passivation layer 16. A second surface 152 (e.g., a bottom surface) of the first conductive via 15 may be substantially aligned with the second surface 162 of the first bottom passivation layer 16.

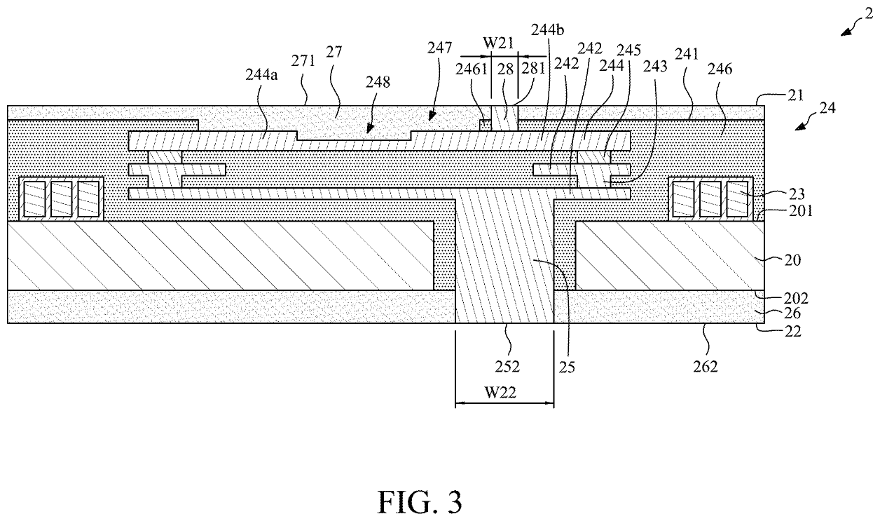

FIG. 3 is an enlarged cross-sectional view of the second portion of the electronic structure 5 of FIG. 1. The second portion may be a second electronic device 2. The second electronic device 2 may be similar to the first electronic device 1 of FIG. 2.

The second electronic device 2 may have a first surface 21 (e.g., a top surface) and a second surface 22 (e.g., a bottom surface) opposite to the first surface 21. The second electronic device 2 may include a second substrate 20, a capacitor cell 23, a second conductive structure 24, a second bottom passivation layer 26, at least one second external connector (e.g., a second conductive via 25 or a second connection via 28) and a second top passivation layer 27.

In some embodiments, the second substrate 20 may be same as or similar to the first substrate 10 of FIG. 2. The second substrate 20 may have a first surface 201 (e.g., a top surface) and a second surface 202 (e.g., a bottom surface) opposite to the first surface 201. The capacitor cell 23 may be disposed on or disposed over the first surface 201 of the second substrate 20. In some embodiments, the capacitor cell 23 may be embedded in the second substrate 20.

The second conductive structure 24 may be same as or similar to the first conductive structure 14 of FIG. 2. The second conductive structure 24 may be disposed on or disposed over the first surface 201 of the second substrate 20, may have a first surface 241 (e.g., a top surface).

The second conductive structure 24 may include a plurality of patterned metal layers 242, a plurality of inner vias 243, a second test pad 244, at least one inner via 245 and a dielectric structure 246. The dielectric structure 246 may include one or more dielectric layers. The patterned metal layers 242, the inner vias 243, the second test pad 244, the inner via 245 and the capacitor cell 23 may be embedded in or may be covered by the dielectric structure 246.

The patterned metal layers 242 may be patterned circuit layers 242, and may be electrically connected to each other by the inner vias 243. The second test pad 244 may be electrically connected to the patterned metal layers 242 through the inner via 245.

The second test pad 244 may be configured to be contacted by a probe during a testing process. The second test pad 244 may include a first portion 244a and a second portion 244b. The dielectric structure 246 may define a second opening 247 to expose the first portion 244a of the second test pad 244. The first portion 244a may be configured to be contacted by the probe during the testing process. Thus, the first portion 244a of the second test pad 244 may have a probe mark 248 thereon after the testing process. In addition, the second portion 244b may be covered by a portion 2461 of the dielectric structure 246. That is, the size of the second opening 247 may be less than the size of the second test pad 244.

The second top passivation layer 27 may be disposed on or disposed over the first surface 241 of the second conductive structure 24, and may surround the second external connector (e.g., a second connection via 28). As shown in FIG. 3, the second top passivation layer 27 may cover the first surface 241 of the second conductive structure 24, and may extend into the second opening 247 and the probe mark 248. The second top passivation layer 27 may have a first surface 271 (e.g., a top surface). The first surface 271 of the second top passivation layer 27 may be the first surface 21 of the second electronic device 2. A material of the second top passivation layer 27 may include oxide material or nitride material, such as silicon nitride (Si₃N₄, or SiN), silicon dioxide (SiO₂), silicon oxynitride (N₂OSi₂), silicon nitride oxide (SiON), tantalum pentoxide (Ta₂O₅), aluminum oxide (Al₂O₃), strontium bismuth tantalum oxide (SrBi₂Ta₂O₉, SBT), barium strontium titanate oxide (BaSrTiO₃, BST), or a combination thereof.

The second external connector may include a second connection via 28. The second connection via 28 may be electrically connected and physically connected to the second portion 244b of the second test pad 244, and may be exposed from the first surface 21 of the second electronic device 2 for an external electrical connection. A material of the second connection via 28 may be copper. The second connection via 28 may extend through the second top passivation layer 27 and the portion 2461 of the dielectric structure 246 of the second conductive structure 24 on the second test pad 244, and may be disposed right above the second test pad 244. A first surface 281 (e.g., a top surface) of the second connection via 28 may be substantially aligned with the first surface 271 of the second top passivation layer 27. Thus, the second connection via 28 may be exposed from the first surface 21 of the second electronic device 2 for external electrical connection. The second connection via 28 may be also referred to as a contact via. In addition, the second test pad 244 may be disposed between the second conductive via 25 and the second connection via 28 in a vertical direction.

The second bottom passivation layer 26 may be disposed on or disposed over the second surface 202 of the second substrate 20 and may surround the second external connector (e.g., a second conductive via 25). The second bottom passivation layer 26 may have a second surface 262 (e.g., a bottom surface). The second surface 262 of the second bottom passivation layer 26 may be the second surface 22 of the second electronic device 2.

The second external connector may further include a second conductive via 25. The second conductive via 25 may be electrically connected to the patterned metal layers 242 of the second conductive structure 24, and may be exposed from the second surface 22 of the second electronic device 2 for an external electrical connection. The second conductive via 25 may extend through the second substrate 20, and may be disposed right under the patterned metal layers 242 of the second conductive structure 24.

As shown in FIG. 3, a length of the second conductive via 25 may be greater than a thickness of the second substrate 20. Thus, the second conductive via 25 may extend beyond the second surface 202 of the second substrate 20. In addition, the second conductive via 25 may further extend through the second bottom passivation layer 26. A second surface 252 (e.g., a bottom surface) of the second conductive via 25 may be substantially aligned with the second surface 262 of the second bottom passivation layer 26. In addition, a width W21 of the second connection via 28 may be less than a width W22 of the second conductive via 25. The width W21 of the second connection via 28 may be less than a width W12 of the first conductive via 15 of FIG. 2.

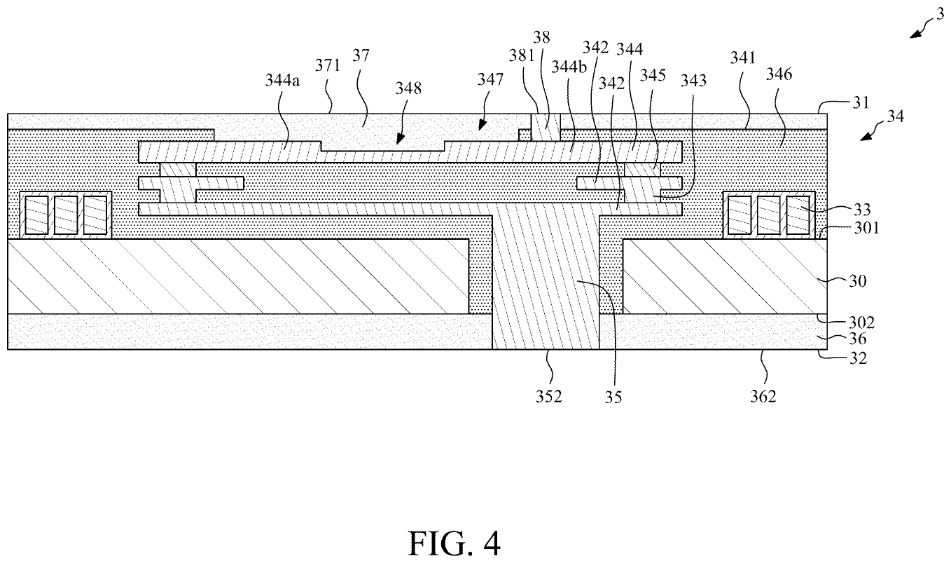

FIG. 4 is an enlarged cross-sectional view of the third portion of the electronic structure 5 of FIG. 1. The third portion may be a third electronic device 3. The third electronic device 3 may be same as or similar to the second electronic device 2 of FIG. 3.

The third electronic device 3 may have a first surface 31 (e.g., a top surface) and a second surface 32 (e.g., a bottom surface) opposite to the first surface 31. The third electronic device 3 may include a third substrate 30, a capacitor cell 33, a third conductive structure 34, a third bottom passivation layer 36, at least one third external connector (e.g., a third conductive via 35 or a third connection via 38) and a third top passivation layer 37.

In some embodiments, the third substrate 30 may be same as or similar to the second substrate 20 of FIG. 3. The third substrate 30 may have a first surface 301 (e.g., a top surface) and a second surface 302 (e.g., a bottom surface) opposite to the first surface 301. The capacitor cell 33 may be disposed on or disposed over the first surface 301 of the third substrate 30.

The third conductive structure 34 may be same as or similar to the second conductive structure 24 of FIG. 3. The third conductive structure 34 may be disposed on or disposed over the first surface 301 of the third substrate 30, may have a first surface 341 (e.g., a top surface).

The third conductive structure 34 may include a plurality of patterned metal layers 342, a plurality of inner vias 343, a third test pad 344, at least one inner via 345 and a dielectric structure 346. The dielectric structure 346 may include one or more dielectric layers. The patterned metal layers 342, the inner vias 343, the third test pad 344, the inner via 345 and the capacitor cell 33 may be embedded in or may be covered by the dielectric structure 346.

The patterned metal layers 342 may be patterned circuit layers 342, and may be electrically connected to each other by the inner vias 343. The third test pad 344 may be electrically connected to the patterned metal layers 342 through the inner via 345.

The third test pad 344 may include a first portion 344a and a second portion 344b. The dielectric structure 346 may define a third opening 347 to expose the first portion 344a of the third test pad 344. The first portion 344a may be configured to be contacted by the probe during the testing process. Thus, the first portion 344a of the third test pad 344 may have a probe mark 348 thereon after the testing process. In addition, the second portion 344b may be covered by the dielectric structure 346.

The third top passivation layer 37 may be disposed on or disposed over the first surface 341 of the third conductive structure 34, and may surround the third external connector (e.g., a third connection via 38). As shown in FIG. 4, the third top passivation layer 37 may cover the first surface 341 of the third conductive structure 34, and may extend into the third opening 347 and the probe mark 348. The third top passivation layer 37 may have a first surface 371 (e.g., a top surface). The first surface 371 of the third top passivation layer 37 may be the first surface 31 of the third electronic device 3.

The third external connector may include a third connection via 38. The third connection via 38 may be electrically connected and physically connected to the second portion 344b of the third test pad 344, and may be exposed from the first surface 31 of the third electronic device 3 for an external electrical connection. The third connection via 38 may extend through the third top passivation layer 37 and a portion of the dielectric structure 346 of the third conductive structure 34 on the third test pad 344, and may be disposed right above the third test pad 344.

A first surface 381 (e.g., a top surface) of the third connection via 38 may be substantially aligned with the first surface 371 of the third top passivation layer 37. Thus, the third connection via 38 may be exposed from the first surface 31 of the third electronic device 3 for external electrical connection.

The third bottom passivation layer 36 may be disposed on or disposed over the second surface 302 of the third substrate 30 and may surround the third external connector (e.g., a third conductive via 35). The third bottom passivation layer 36 may have a second surface 362 (e.g., a bottom surface). The second surface 362 of the third bottom passivation layer 36 may be the second surface 32 of the third electronic device 3.

The third external connector may further include a third conductive via 35. The third conductive via 35 may be electrically connected to the patterned metal layers 342 of the third conductive structure 34, and may be exposed from the second surface 32 of the third electronic device 3 for an external electrical connection. The third conductive via 35 may extend through the third substrate 30, and may be disposed right under the patterned metal layers 342 of the third conductive structure 34.

The third conductive via 35 may extend beyond the second surface 302 of the third substrate 30. In addition, the third conductive via 35 may further extend through the third bottom passivation layer 36. A second surface 352 (e.g., a bottom surface) of the third conductive via 35 may be substantially aligned with the second surface 362 of the third bottom passivation layer 36. In addition, a width of the third connection via 38 may be less than a width of the third conductive via 35. The width of the third connection via 38 may be less than a width W22 of the second conductive via 25 of FIG. 3.

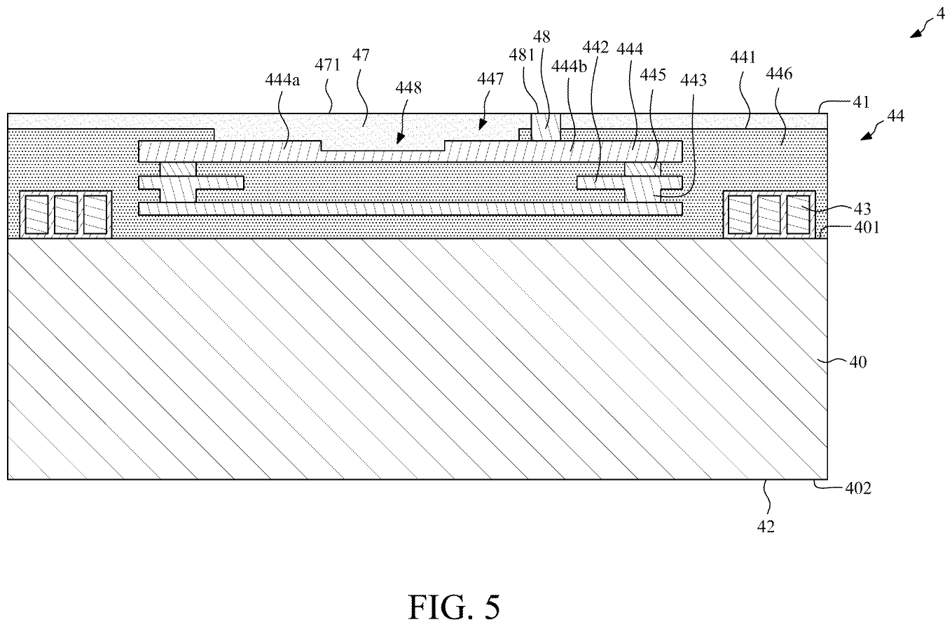

FIG. 5 is an enlarged cross-sectional view of the fourth portion of the electronic structure 5 of FIG. 1. The fourth portion may be a fourth electronic device 4. The fourth electronic device 4 may be same as or similar to the third electronic device 3 of FIG. 4.

The fourth electronic device 4 may have a first surface 41 (e.g., a top surface) and a second surface 42 (e.g., a bottom surface) opposite to the first surface 41. The fourth electronic device 4 may include a fourth substrate 40, a capacitor cell 43, a fourth conductive structure 44, at least one fourth external connector (e.g., a fourth connection via 48) and a fourth top passivation layer 47.

In some embodiments, the fourth substrate 40 may be same as or similar to the third substrate 30 of FIG. 4. The fourth substrate 40 may have a first surface 401 (e.g., a top surface) and a second surface 402 (e.g., a bottom surface) opposite to the first surface 401. The capacitor cell 43 may be disposed on or disposed over the first surface 401 of the fourth substrate 40.

The fourth conductive structure 44 may be same as or similar to the third conductive structure 34 of FIG. 4. The fourth conductive structure 44 may be disposed on or disposed over the first surface 401 of the fourth substrate 40, may have a first surface 441 (e.g., a top surface).

The fourth conductive structure 44 may include a plurality of patterned metal layers 442, a plurality of inner vias 443, a fourth test pad 444, at least one inner via 445 and a dielectric structure 446. The dielectric structure 446 may include one or more dielectric layers. The patterned metal layers 442, the inner vias 443, the fourth test pad 444, the inner via 445 and the capacitor cell 43 may be embedded in or may be covered by the dielectric structure 446.

The patterned metal layers 442 may be patterned circuit layers 442, and may be electrically connected to each other by the inner vias 443. The fourth test pad 444 may be electrically connected to the patterned metal layers 442 through the inner via 445.

The fourth test pad 444 may include a first portion 444a and a second portion 444b. The dielectric structure 446 may define a fourth opening 447 to expose the first portion 444a of the fourth test pad 444. The first portion 444a may be configured to be contacted by the probe during the testing process. Thus, the first portion 444a of the fourth test pad 444 may have a probe mark 448 thereon after the testing process. In addition, the second portion 444b may be covered by the dielectric structure 446.

The fourth top passivation layer 47 may be disposed on or disposed over the first surface 441 of the fourth conductive structure 44, and may surround the fourth external connector (e.g., a fourth connection via 48). As shown in FIG. 5, the fourth top passivation layer 47 may cover the first surface 441 of the fourth conductive structure 44, and may extend into the fourth opening 447 and the probe mark 448. The fourth top passivation layer 47 may have a first surface 471 (e.g., a top surface). The first surface 471 of the fourth top passivation layer 47 may be the first surface 41 of the fourth electronic device 4.

The fourth external connector may include a fourth connection via 48. The fourth connection via 48 may be electrically connected and physically connected to the second portion 444b of the fourth test pad 444, and may be exposed from the first surface 41 of the fourth electronic device 4 for an external electrical connection. The fourth connection via 48 may extend through the fourth top passivation layer 47 and a portion of the dielectric structure 446 of the fourth conductive structure 44 on the fourth test pad 444, and may be disposed right above the fourth test pad 444.

A first surface 481 (e.g., a top surface) of the fourth connection via 48 may be substantially aligned with the first surface 471 of the fourth top passivation layer 47. Thus, the fourth connection via 48 may be exposed from the first surface 41 of the fourth electronic device 4 for external electrical connection.

As shown in FIG. 1, the second conductive structure 24 may be disposed under the first substrate 10, and the first conductive structure 14 of the first electronic device 1 may be electrically connected to the second conductive structure 24 of the second electronic device 2 through the first conductive via 15 and the second connection via 28 so as to form a first vertical electrical path 71. Thus, a first electrical path between the first conductive structure 14 of the first electronic device 1 and the second conductive structure 24 of the second electronic device 2 may include the first vertical electrical path 71. The first electrical path (including the first vertical electrical path 71) may be located between the first test pad 144 and the second test pad 244. For example, the first electrical path (including the first vertical electrical path 71) is within a vertical projection of the first test pad 144. Thus, a projection of the first vertical electrical path 71 on the second test pad 244 is within a projection of the first test pad 144 on the second test pad 244. Further, the first vertical electrical path 71 may pass through the first substrate 10. In addition, the first electrical path may pass through the second portion 244b of the second test pad 244. Thus, the second portion 244b of the second test pad 244 may be a portion of the first electrical path between the first conductive structure 14 of the first electronic device 1 and the second conductive structure 24 of the second electronic device 2.

Similarly, the third conductive structure 34 may be disposed under the second substrate 20, and the second conductive structure 24 of the second electronic device 2 may be electrically connected to the third conductive structure 34 of the third electronic device 3 through the second conductive via 25 and the third connection via 38 so as to form a second vertical electrical path 72. Thus, a second electrical path between the second conductive structure 24 of the second electronic device 2 and the third conductive structure 34 of the third electronic device 3 may include the second vertical electrical path 72. The second electrical path (including the second vertical electrical path 72) may be located between the second test pad 244 and the third test pad 344. For example, the second electrical path (including the second vertical electrical path 72) is within a vertical projection of the second test pad 244. Thus, a projection of the second vertical electrical path 72 on the third test pad 344 is within a projection of the second test pad 244 on the third test pad 344. Further, the second vertical electrical path 72 may pass through the second substrate 20. In addition, the second electrical path may pass through the second portion 344b of the third test pad 344. Thus, the second portion 344b of the third test pad 344 may be a portion of the second electrical path between the second conductive structure 24 of the second electronic device 2 and the third conductive structure 34 of the third electronic device 3.

Similarly, the fourth conductive structure 44 may be disposed under the third substrate 30, and the third conductive structure 34 of the third electronic device 3 may be electrically connected to the fourth conductive structure 44 of the fourth electronic device 4 through the third conductive via 35 and the fourth connection via 48 so as to form a third vertical electrical path 73. Thus, a third electrical path between the third conductive structure 34 of the third electronic device 3 and the fourth conductive structure 44 of the fourth electronic device 4 may include the third vertical electrical path 73. The third electrical path (including the third vertical electrical path 73) may be located between the third test pad 344 and the fourth test pad 444. For example, the third electrical path (including the third vertical electrical path 73) is within a vertical projection of the third test pad 344. Thus, a projection of the third vertical electrical path 73 on the fourth test pad 444 is within a projection of the third test pad 344 on the fourth test pad 444. Further, the third vertical electrical path 73 may pass through the third substrate 30. In addition, the third electrical path may pass through the second portion 444b of the fourth test pad 444. Thus, the second portion 444b of the fourth test pad 444 may be a portion of the third electrical path between the third conductive structure 34 of the third electronic device 3 and the fourth conductive structure 44 of the fourth electronic device 4.

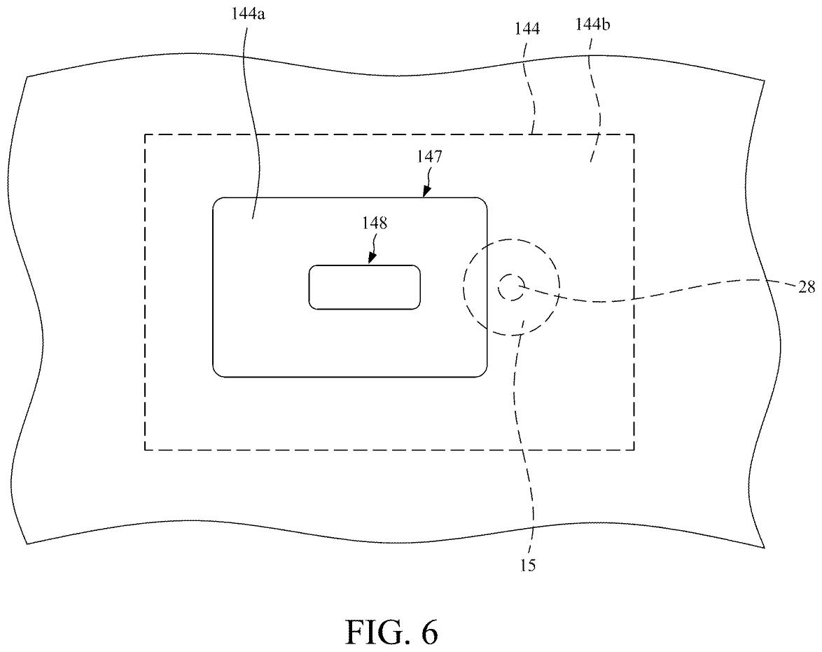

FIG. 6 is a partially enlarged top view of the electronic structure 5 of FIG. 1. As shown in FIG. 1 and FIG. 6, a vertical projection of the external connector (including, for example, the first conductive via 15 and the second connection via 28) may overlap or may be disposed within a vertical projection of the first test pad 144. In addition, the vertical projection of the external connector (including, for example, the first conductive via 15) may overlap a vertical projection of the first opening 147. The vertical projection of the external connector (including, for example, the second connection via 28) may be located outside the vertical projection of the first opening 147.

In the embodiment illustrated in FIG. 1 to FIG. 6, the first electronic device 1, the second electronic device 2, the third electronic device 3 and the fourth electronic device 4 may be bonded directly to one another by hybrid bonding. Thus, a height of the electronic structure 5 may be reduced. Further, the bonding solder and underfill are not used so as to lower the manufacturing cost of the electronic structure 5 and avoid the high resistance issue. In addition, the external connector (including, for example, the first conductive via 15 and the second connection via 28) may located right under the first test pad 144, thus, a vertical space occupied by the external connector (including, for example, the first conductive via 15 and the second connection via 28) and the first test pad 144 may be reduced, which may be an efficient space design. In addition, the test pad 144, 244, 344, 444 may be used for probing and may be a portion of the electrical path, thus, the flexibility of layout design is improved.

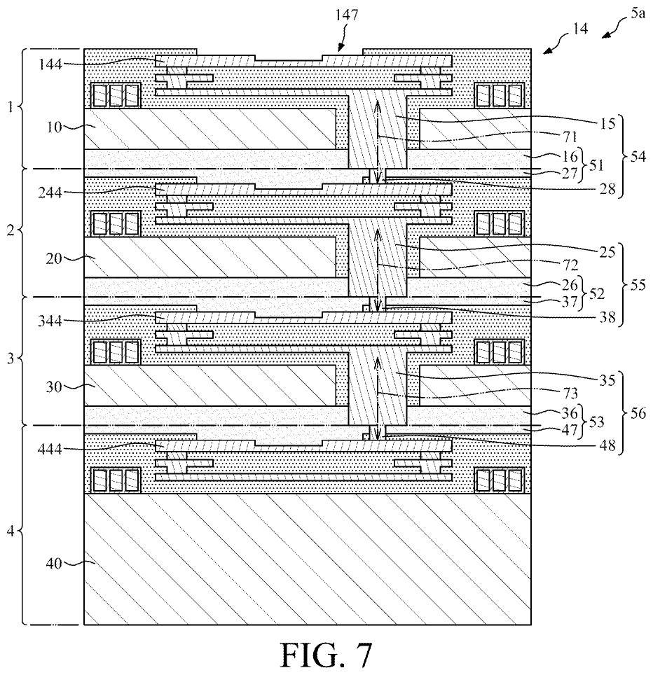

FIG. 7 is a schematic cross-sectional view of an electronic structure 5a in accordance with some embodiments of the present disclosure. The electronic structure 5a may be similar to the electronic structure 5 of FIG. 1, and the differences are described as follows.

The first conductive via 15 and the second connection via 28 may contact each other or may be fused together to form a first interconnection pillar 54. The first interconnection pillar 54 may be a monolithic structure, and there may be no interface between the first conductive via 15 and the second connection via 28. The first interconnection pillar 54 may electrically connecting the first conductive structure 14 and the second conductive structure 24, and may form the first electrical path (including the first vertical electrical path 71). In addition, the first bottom passivation layer 16 and the second top passivation layer 27 may contact each other or may be fused together to form a first bonding layer 51. The first bonding layer 51 may be a monolithic structure, and there may be no interface between the first bottom passivation layer 16 and the second top passivation layer 27. The first bonding layer 51 may be used for bonding the first substrate 10 and the second conductive structure 24. A portion of the first conductive via 15 and a portion of the second connection via 28 may be embedded in the first bonding layer 51. The first electrical path (including the first vertical electrical path 71) may pass through the first bonding layer 51. In addition, the first bonding layer 51 may extend into the second opening 247 to contact the first portion 244a of the second test pad 244.

Similarly, the second conductive via 25 and the third connection via 38 may contact each other or may be fused together to form a second interconnection pillar 55. The second interconnection pillar 55 may be a monolithic structure, and there may be no interface between the second conductive via 25 and the third connection via 38. The second interconnection pillar 55 may electrically connecting the second conductive structure 24 and the third conductive structure 34, and may form the second electrical path (including the second vertical electrical path 72). In addition, the second bottom passivation layer 26 and the third top passivation layer 37 may contact each other or may be fused together to form a second bonding layer 52. The second bonding layer 52 may be a monolithic structure, and there may be no interface between the second bottom passivation layer 26 and the third top passivation layer 37. The second bonding layer 52 may be used for bonding the second substrate 20 and the third conductive structure 34. A portion of the second conductive via 25 and a portion of the third connection via 38 may be embedded in the second bonding layer 52. The second electrical path (including the second vertical electrical path 72) may pass through the second bonding layer 52. In addition, the second bonding layer 52 may extend into the third opening 347 to contact the first portion 344a of the third test pad 344.

Similarly, the third conductive via 35 and the fourth connection via 48 may contact each other or may be fused together to form a third interconnection pillar 56. The third interconnection pillar 56 may be a monolithic structure, and there may be no interface between the third conductive via 35 and the fourth connection via 48. The third interconnection pillar 56 may electrically connecting the third conductive structure 34 and the fourth conductive structure 44, and may form the third electrical path (including the third vertical electrical path 73). In addition, the third bottom passivation layer 36 and the fourth top passivation layer 47 may contact each other or may be fused together to form a third bonding layer 53. The third bonding layer 53 may be a monolithic structure, and there may be no interface between the third bottom passivation layer 36 and the fourth top passivation layer 47. The third bonding layer 53 may be used for bonding the third substrate 30 and the fourth conductive structure 44. A portion of the third conductive via 35 and a portion of the fourth connection via 48 may be embedded in the third bonding layer 53. The third electrical path (including the third vertical electrical path 73) may pass through the third bonding layer 53. In addition, the third bonding layer 53 may extend into the fourth opening 447 to contact the first portion 444a of the fourth test pad 444.

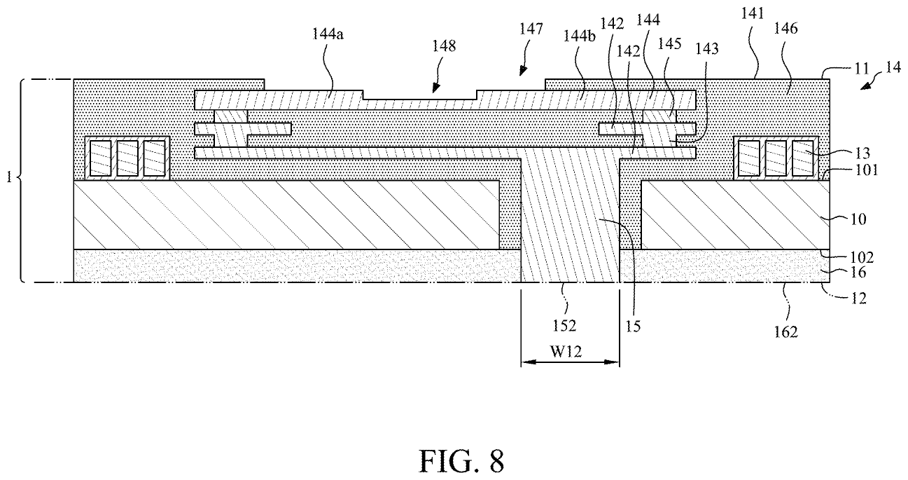

FIG. 8 is an enlarged cross-sectional view of the first portion of the electronic structure 5a of FIG. 7. The first portion may be substantially a first electronic device 1. The first electronic device 1 of FIG. 8 may be similar to the first electronic device 1 of FIG. 2, except that the second surface 12 of the first electronic device 1, the second surface 162 of the first bottom passivation layer 16 and the second surface 152 of the first conductive via 15 may be imaginary surfaces rather than actual surfaces.

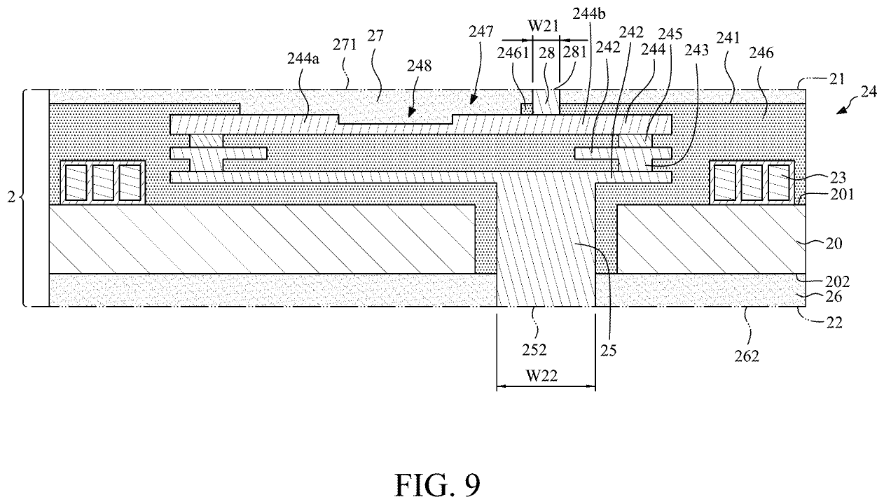

FIG. 9 is an enlarged cross-sectional view of the second portion of the electronic structure 5a of FIG. 7. The second portion may be a substantially second electronic device 2. The second electronic device 2 of FIG. 9 may be similar to the second electronic device 2 of FIG. 3, except that the first surface 21 of the second electronic device 2, the first surface 271 of the second top passivation layer 27 and the first surface 281 of the second connection via 28 may be imaginary surfaces rather than actual surfaces. In addition, the second surface 22 of the second electronic device 2, the second surface 262 of the second bottom passivation layer 26 and the second surface 252 of the second conductive via 25 may be imaginary surfaces rather than actual surfaces.

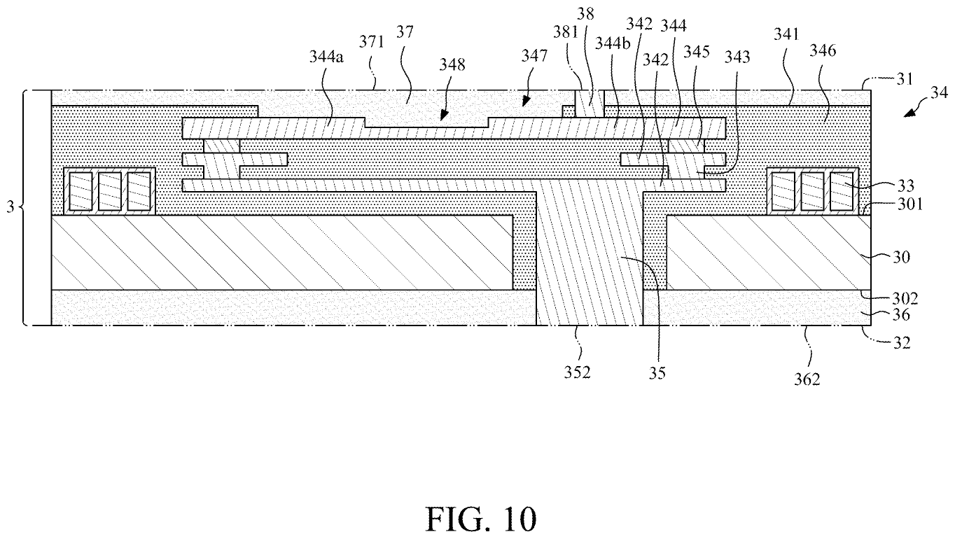

FIG. 10 is an enlarged cross-sectional view of the third portion of the electronic structure 5a of FIG. 7. The third portion may be a substantially third electronic device 3. The third electronic device 3 of FIG. 10 may be similar to the third electronic device 3 of FIG. 4, except that the first surface 31 of the third electronic device 3, the first surface 371 of the third top passivation layer 37 and the first surface 381 of the third connection via 38 may be imaginary surfaces rather than actual surfaces. In addition, the second surface 32 of the third electronic device 3, the second surface 362 of the third bottom passivation layer 36 and the second surface 352 of the third conductive via 35 may be imaginary surfaces rather than actual surfaces.

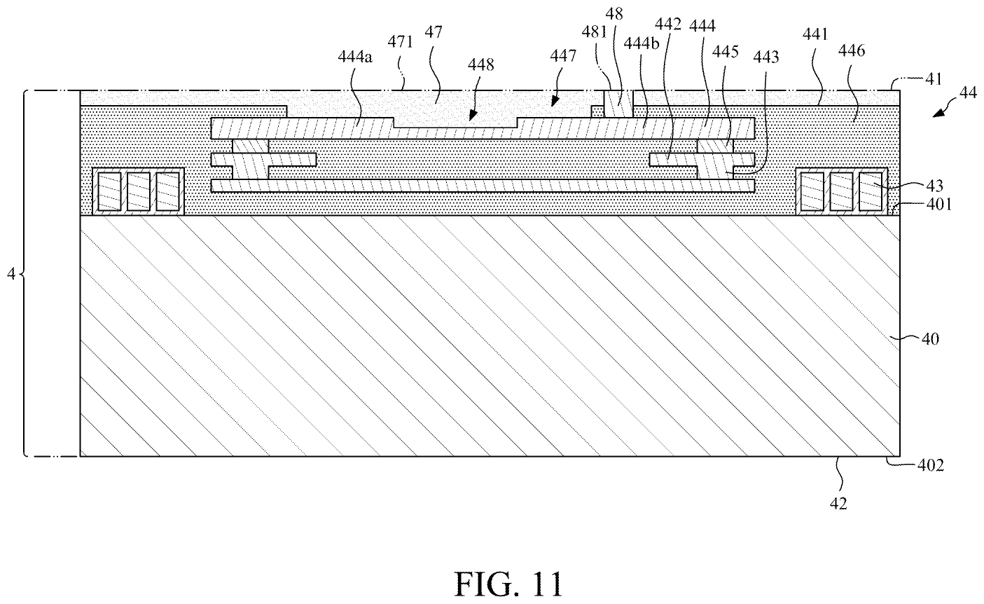

FIG. 11 is an enlarged cross-sectional view of the fourth portion of the electronic structure 5a of FIG. 7. The fourth portion may be a substantially fourth electronic device 4. The fourth electronic device 4 of FIG. 11 may be similar to the fourth electronic device 4 of FIG. 5, except that the first surface 41 of the fourth electronic device 4, the first surface 471 of the fourth top passivation layer 47 and the first surface 481 of the fourth connection via 48 may be imaginary surfaces rather than actual surfaces.

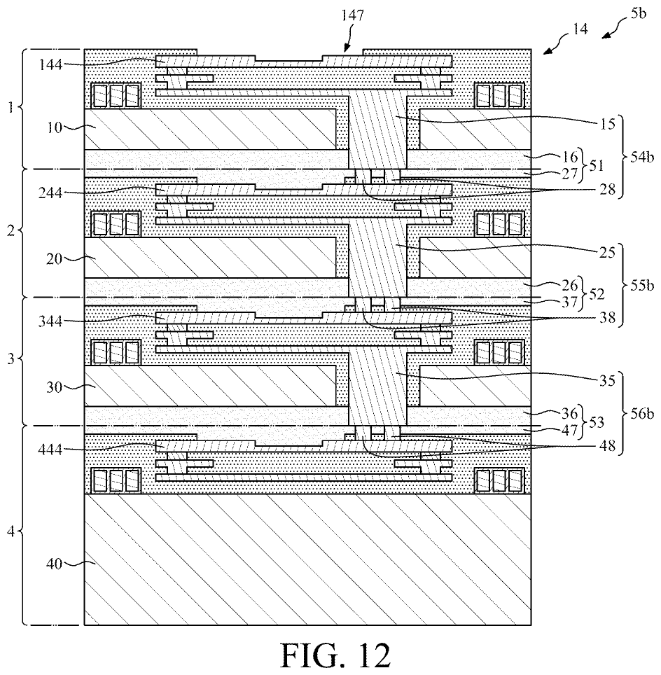

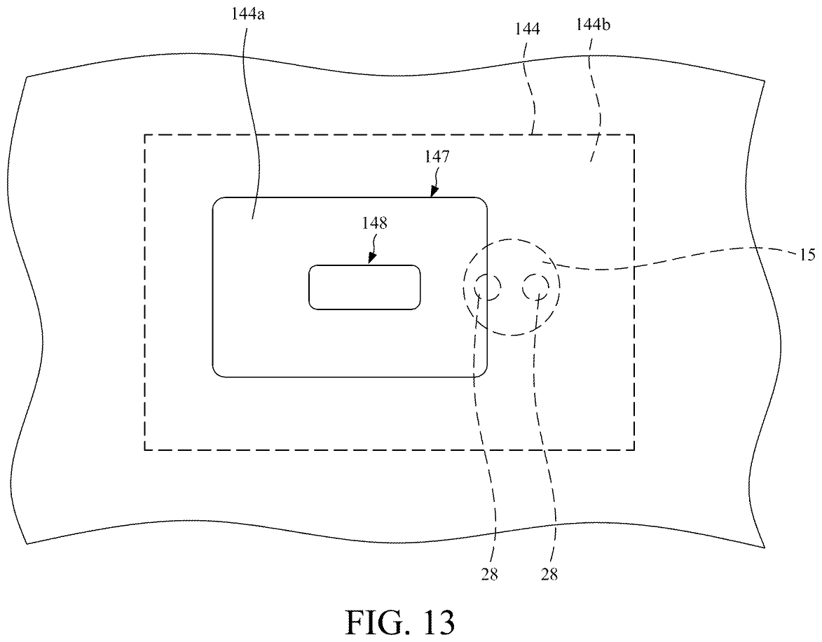

FIG. 12 is a schematic cross-sectional view of an electronic structure 5b in accordance with some embodiments of the present disclosure. FIG. 13 is a partially enlarged top view of the electronic structure 5b of FIG. 12. The electronic structure 5b of FIG. 12 may be similar to the electronic structure 5a of FIG. 7, and the differences are described as follows.

The first interconnection pillar 54b may include one first conductive via 15 and a plurality of second connection vias 28. A width of each of the second connection vias 28 (e.g., the width W21 of the second connection via 28 of FIG. 9) may be less than a width of the first conductive via 15 (e.g., the width W12 of the first conductive via of FIG. 8). Further, the second interconnection pillar 55b may include one second conductive via 25 and a plurality of third connection vias 38. A width of each of the third connection vias 38 may be less than a width of the second conductive via 25. In addition, the third interconnection pillar 56b may include one third conductive via and a plurality of fourth connection vias 48. A width of each of the fourth connection vias 48 may be less than a width of the third conductive via 35.

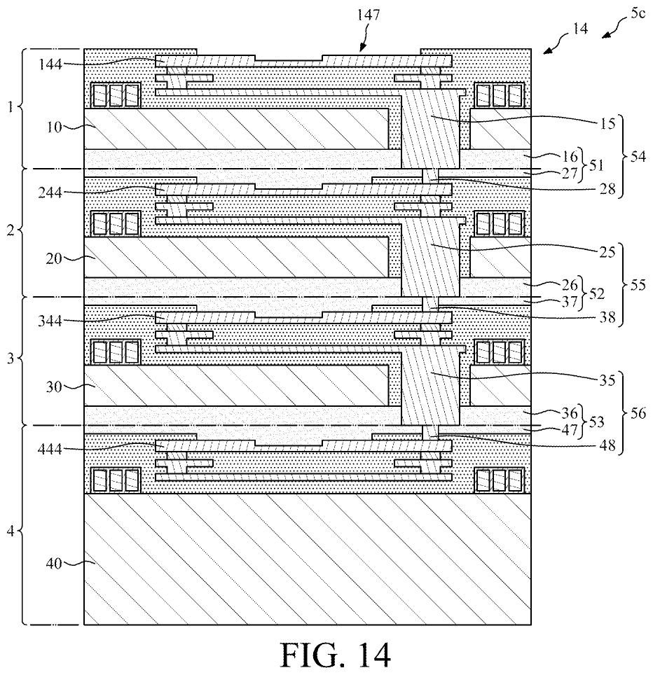

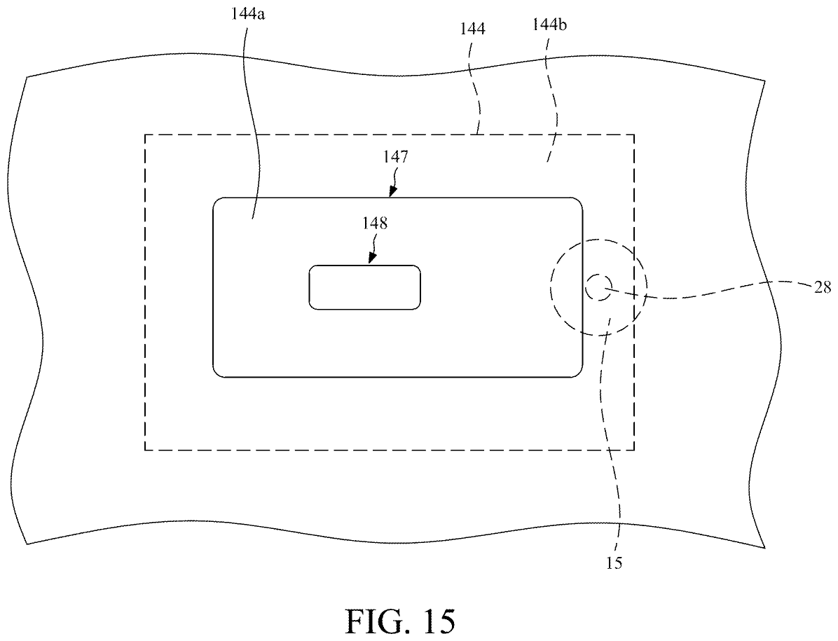

FIG. 14 is a schematic cross-sectional view of an electronic structure 5c in accordance with some embodiments of the present disclosure. FIG. 15 is a partially enlarged top view of the electronic structure 5c of FIG. 14. The electronic structure 5c of FIG. 14 may be similar to the electronic structure 5a of FIG. 7, except the positions of the interconnection pillars 54, 55, 56. For example, a vertical portion of the first conductive via 15 may be disposed outside the vertical projection of the first test pad 144. However, the vertical projection of the first conductive via 15 may still overlap the vertical projection of the first test pad 144.

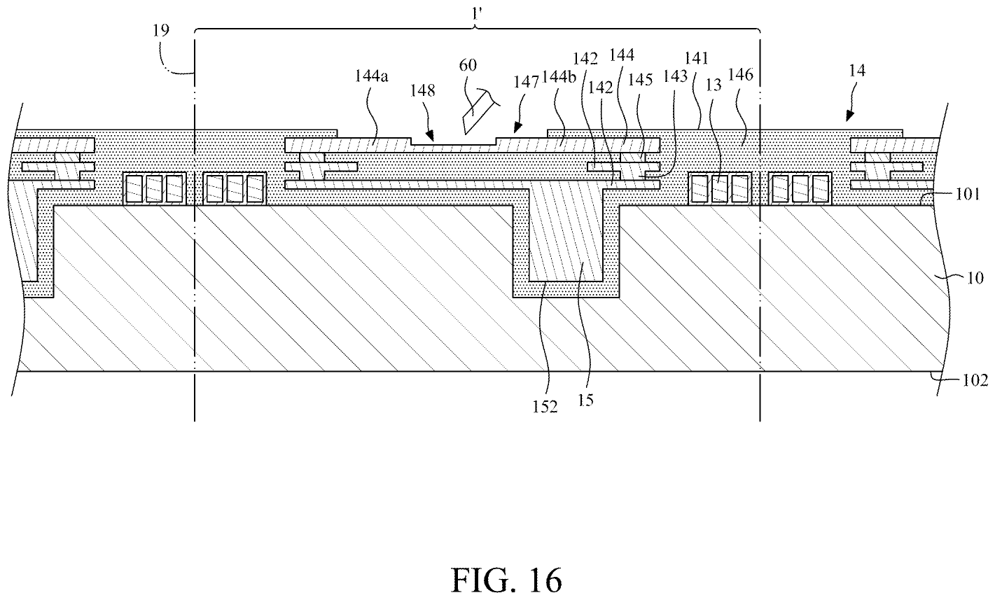

FIG. 16 to FIG. 25 illustrate various stages of a method of manufacturing an electronic structure 5, in accordance with some embodiments of the present disclosure.

Referring to FIG. 16, a first substrate 10 may be provided. The first substrate 10 of FIG. 16 may be same as or similar to the first substrate 10 of FIG. 1 and FIG. 2. The first substrate 10 may have a first surface 101 (e.g., a top surface) and a second surface 102 (e.g., a bottom surface) opposite to the first surface 101. Then, a first conductive via 15 may be formed in the first substrate 10, and a first conductive structure 14 may be formed on the first surface 101 of the first substrate 10. The first conductive via 15 and the first conductive structure 14 may be same as or similar to the first conductive via 15 and the first conductive structure 14 of FIG. 1 and FIG. 2, respectively. The first conductive via 15 may be electrically connected to the first conductive structure 14. The first conductive structure 14 defines a first opening 147 to expose a first portion 144a of a first test pad 144 thereof. The first conductive via 15 is disposed under the first test pad 144.

The first substrate 10 may have a plurality of singulation lines 19 crossed with each other to define a plurality of units 1′. Each of the units 1′ may correspond to the first electronic device 1 of FIG. 2. Then, a testing process may be conducted by using a probe 60. The probe 60 is provided to contact and test the exposed first portion 144a of the first test pad 144 so as to determine the electrical property of the unit 1′. Meanwhile, a probe mark 148 may be recessed from a top surface of the first test pad 144.

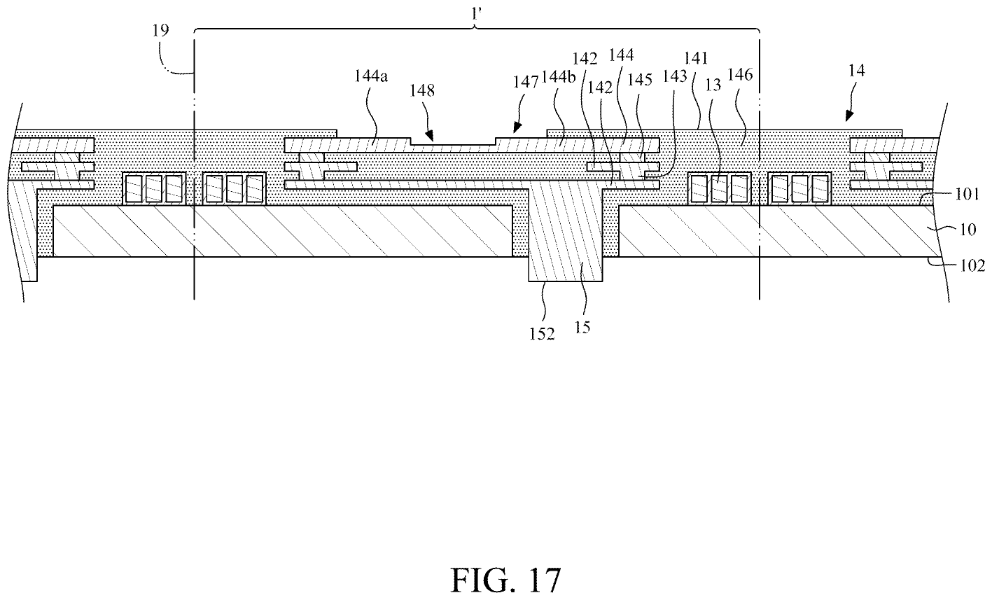

Referring to FIG. 17, the first substrate 10 may be thinned to expose a bottom portion of the first conductive via 15. Then, a first bottom passivation layer 16 may be formed or disposed on the second surface 102 (e.g., bottom surface) of the first substrate 10. The first bottom passivation layer 16 may surround or cover the exposed bottom portion of the first conductive via 15. Then, a grinding process (e.g., chemical mechanical polishing (CMP)) may be conducted to a second surface 162 of the first bottom passivation layer 16 such that a second surface 152 (e.g., a bottom surface) of the first conductive via 15 may be substantially aligned with the second surface 162 of the first bottom passivation layer 16. Then, the first substrate 10 and the first conductive structure 14 may be singulated along the singulation lines 19 as to form a plurality of first electronic devices 1 as shown in FIG. 2.

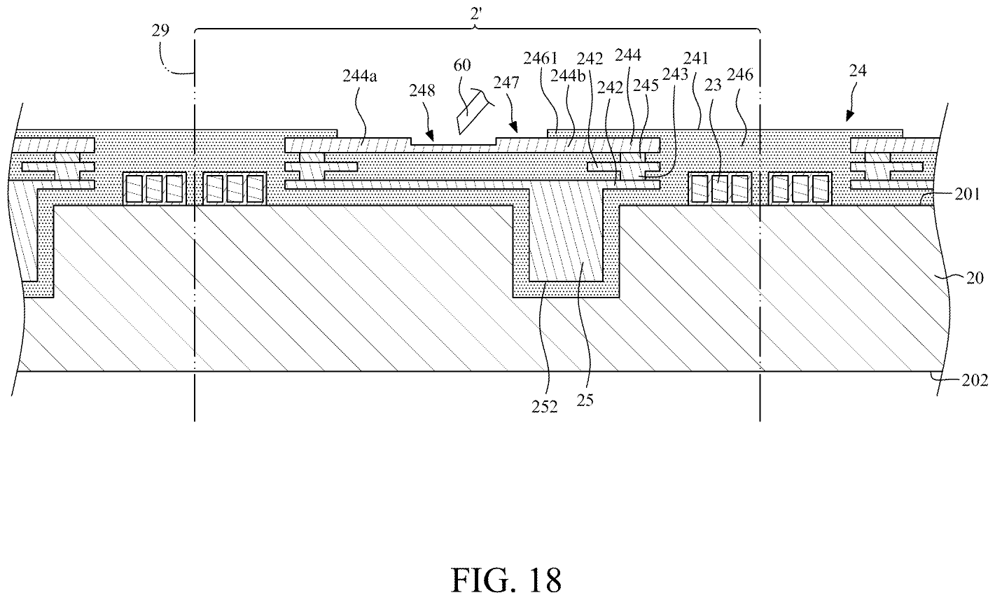

Referring to FIG. 18, a second substrate 20 may be provided. The second substrate 20 of FIG. 18 may be same as or similar to the second substrate 20 of FIG. 1 and FIG. 3. The second substrate 20 may have a first surface 201 (e.g., a top surface) and a second surface 202 (e.g., a bottom surface) opposite to the first surface 201. Then, a second conductive via 25 may be formed in the second substrate 20, and a second conductive structure 24 may be formed on the first surface 201 of the second substrate 20. The second conductive via 25 and the second conductive structure 24 may be same as or similar to the second conductive via 25 and the second conductive structure 24 of FIG. 1 and FIG. 3, respectively. The second conductive via 25 may be electrically connected to the second conductive structure 24. The second conductive structure 24 defines a second opening 247 to expose a first portion 244a of a second test pad 244 thereof. The second conductive via 25 is disposed under the second test pad 244.

The second substrate 20 may have a plurality of singulation lines 29 crossed with each other to define a plurality of units 2′. Each of the units 2′ may correspond to the second electronic device 2 of FIG. 3. Then, a testing process may be conducted by using a probe 60. The probe 60 is provided to contact and test the exposed first portion 244a of the second test pad 244 so as to determine the electrical property of the unit 2′. Meanwhile, a probe mark 248 may be recessed from a top surface of the second test pad 244.

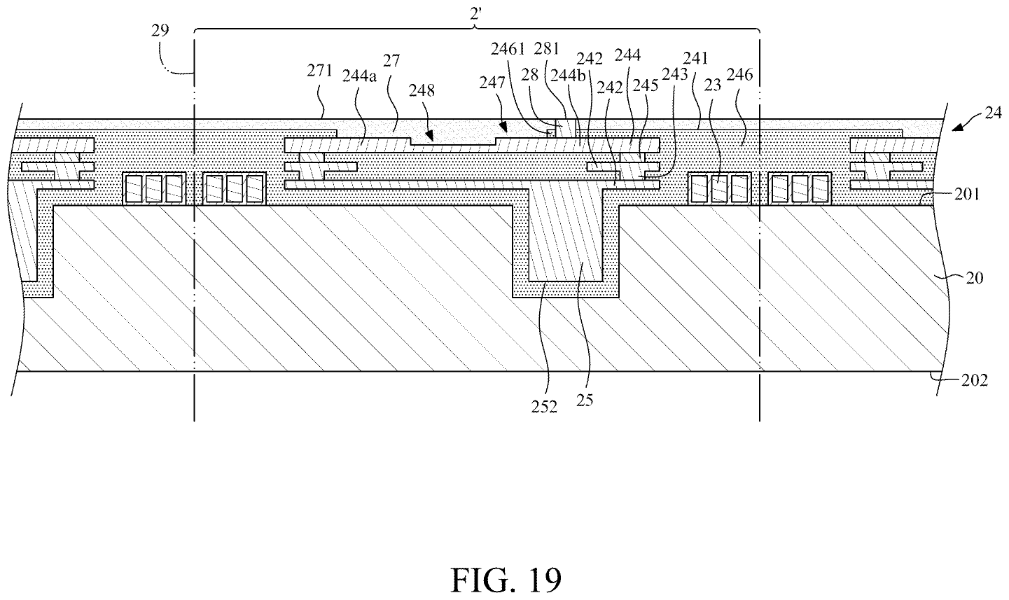

Referring to FIG. 19, a second top passivation layer 27 may be formed or disposed on the first surface 241 of the second conductive structure 24. The second top passivation layer 27 may cover the second opening 247. Then, a second connection via 28 may formed to extend through the second top passivation layer 27 and a portion 2461 of the dielectric structure 246 of the second conductive structure 24 on the second test pad 244 so as to electrically connect and physically connect to the second portion 244b of the second test pad 244. Then, a grinding process (e.g., chemical mechanical polishing (CMP)) may be conducted to a first surface 271 (e.g., top surface) of the second top passivation layer 27 such that a first surface 281 (e.g., a top surface) of the second connection via 28 may be substantially aligned with the first surface 271 of the second top passivation layer 27.

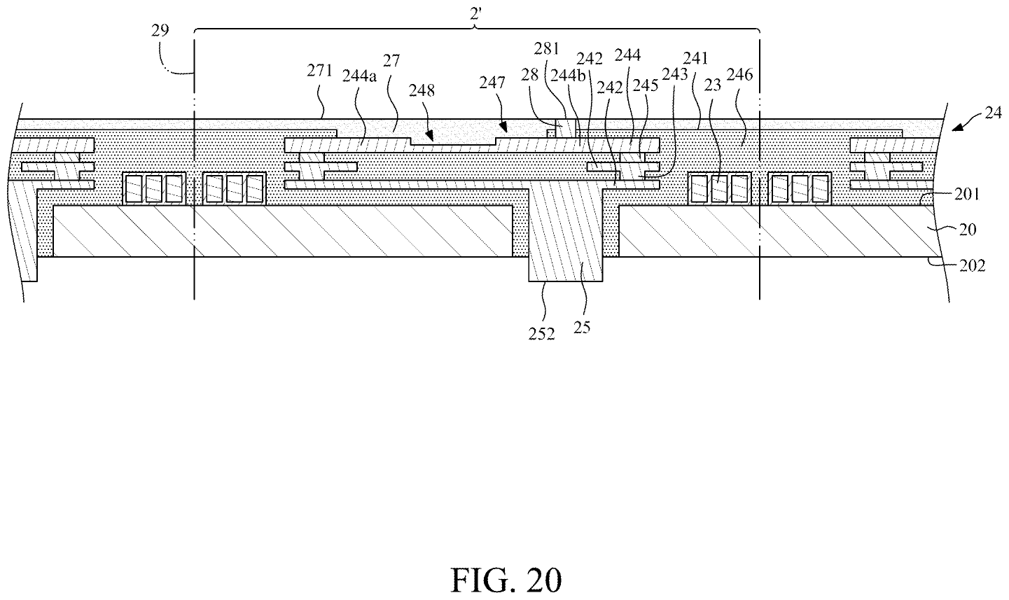

Referring to FIG. 20, the second substrate 20 may be thinned to expose a bottom portion of the second conductive via 25. Then, a second bottom passivation layer 26 may be formed or disposed on the second surface 202 (e.g., bottom surface) of the second substrate 20. The second bottom passivation layer 26 may surround or cover the exposed bottom portion of the second conductive via 25. Then, a grinding process (e.g., chemical mechanical polishing (CMP)) may be conducted to a second surface 262 of the second bottom passivation layer 26 such that a second surface 252 (e.g., a bottom surface) of the second conductive via 25 may be substantially aligned with the second surface 262 of the second bottom passivation layer 26. Then, the second substrate 20 and the second conductive structure 24 may be singulated along the singulation lines 29 as to form a plurality of second electronic devices 2 as shown in FIG. 3.

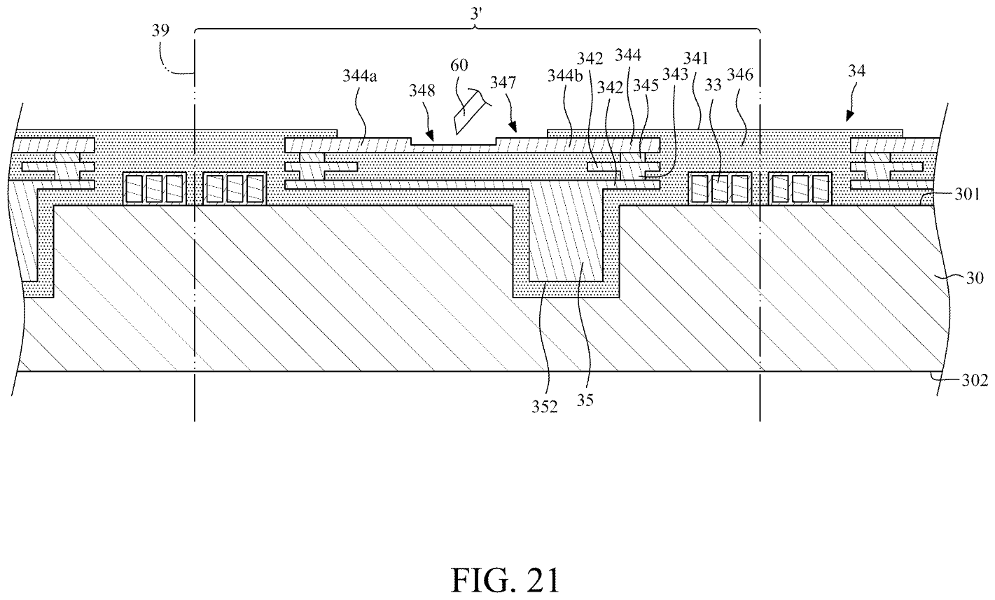

Referring to FIG. 21, a third substrate 30 may be provided. The third substrate 30 of FIG. 21 may be same as or similar to the third substrate 30 of FIG. 1 and FIG. 4. Then, a third conductive via 35 may be formed in the third substrate 30, and a third conductive structure 34 may be formed on the first surface 301 of the third substrate 30. The third conductive via 35 and the third conductive structure 34 may be same as or similar to the third conductive via 35 and the third conductive structure 34 of FIG. 1 and FIG. 4, respectively. The third conductive via 35 may be electrically connected to the third conductive structure 34. The third conductive structure 34 defines a third opening 347 to expose a first portion 344a of a third test pad 344 thereof. The third conductive via 35 is disposed under the third test pad 344.

The third substrate 30 may have a plurality of singulation lines 39 crossed with each other to define a plurality of units 3′. Each of the units 3′ may correspond to the third electronic device 3 of FIG. 4. Then, a testing process may be conducted by using a probe 60. The probe 60 is provided to contact and test the exposed first portion 344a of the third test pad 344 so as to determine the electrical property of the unit 3′. Meanwhile, a probe mark 348 may be recessed from a top surface of the third test pad 344.

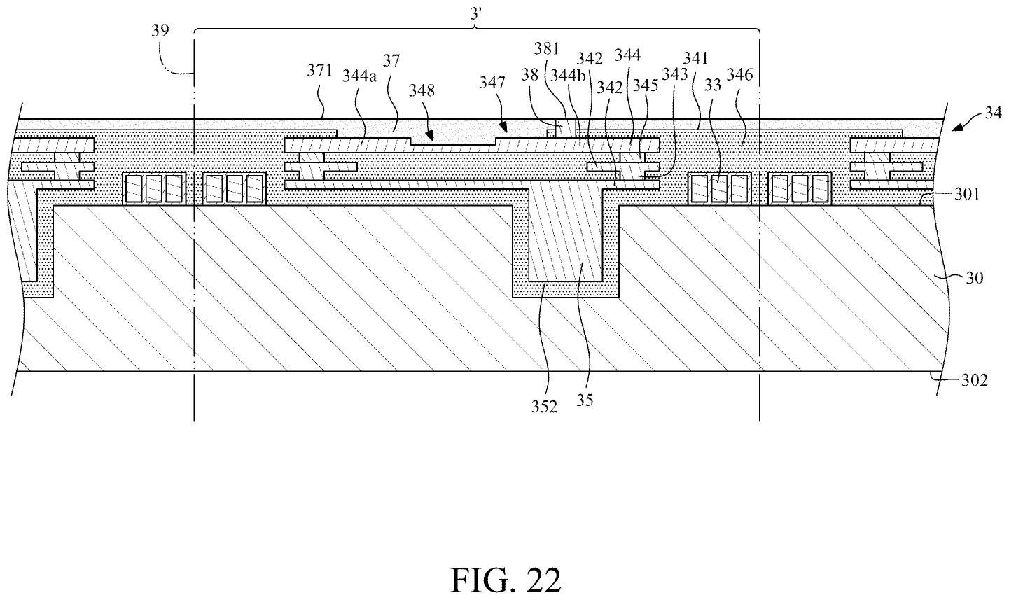

Referring to FIG. 22, a third top passivation layer 37 may be formed or disposed on the first surface 341 of the third conductive structure 34. The third top passivation layer 37 may cover the third opening 347. Then, a third connection via 38 may formed to extend through the third top passivation layer 37 and a portion of the dielectric structure 346 of the third conductive structure 34 on the third test pad 344 so as to electrically connect and physically connect to the second portion 344b of the third test pad 344. Then, a grinding process (e.g., chemical mechanical polishing (CMP)) may be conducted to a first surface 371 (e.g., top surface) of the third top passivation layer 37 such that a first surface 381 (e.g., a top surface) of the third connection via 38 may be substantially aligned with the first surface 371 of the third top passivation layer 37.

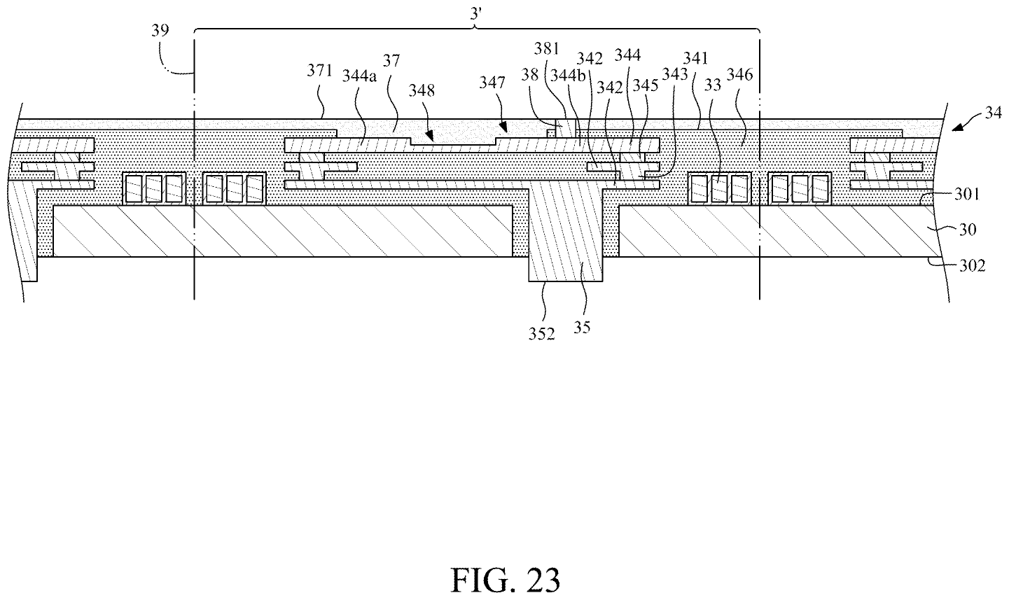

Referring to FIG. 23, the third substrate 30 may be thinned to expose a bottom portion of the third conductive via 35. Then, a third bottom passivation layer 36 may be formed or disposed on the second surface 302 (e.g., bottom surface) of the third substrate 30. The third bottom passivation layer 36 may surround or cover the exposed bottom portion of the third conductive via 35. Then, a grinding process (e.g., chemical mechanical polishing (CMP)) may be conducted to a second surface 362 of the third bottom passivation layer 36 such that a second surface 352 (e.g., a bottom surface) of the third conductive via 35 may be substantially aligned with the second surface 362 of the third bottom passivation layer 36. Then, the third substrate 30 and the third conductive structure 34 may be singulated along the singulation lines 39 as to form a plurality of third electronic devices 3 as shown in FIG. 4.

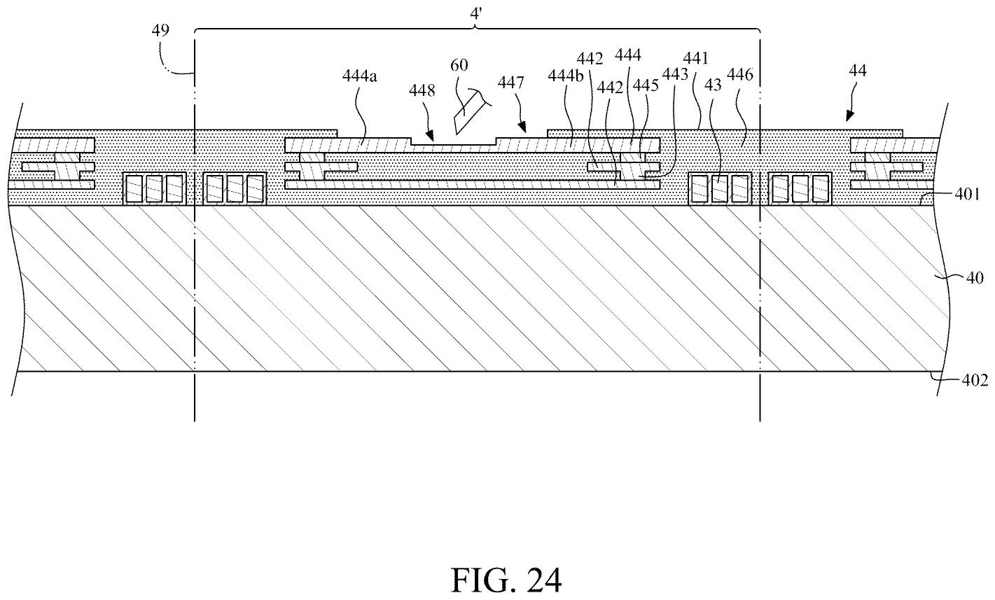

Referring to FIG. 24, a fourth substrate 40 may be provided. The fourth substrate 40 of FIG. 24 may be same as or similar to the third substrate 40 of FIG. 1 and FIG. 5. Then, a fourth conductive structure 44 may be formed on the first surface 401 of the fourth substrate 40. The fourth conductive structure 44 may be same as or similar to the fourth conductive structure 44 of FIG. 1 and FIG. 5. The fourth conductive structure 44 defines a fourth opening 447 to expose a first portion 444a of a fourth test pad 444 thereof.

The fourth substrate 40 may have a plurality of singulation lines 49 crossed with each other to define a plurality of units 4′. Each of the units 4′ may correspond to the fourth electronic device 4 of FIG. 5. Then, a testing process may be conducted by using a probe 60. The probe 60 is provided to contact and test the exposed first portion 444a of the fourth test pad 444 so as to determine the electrical property of the unit 4′. Meanwhile, a probe mark 448 may be recessed from a top surface of the fourth test pad 444.

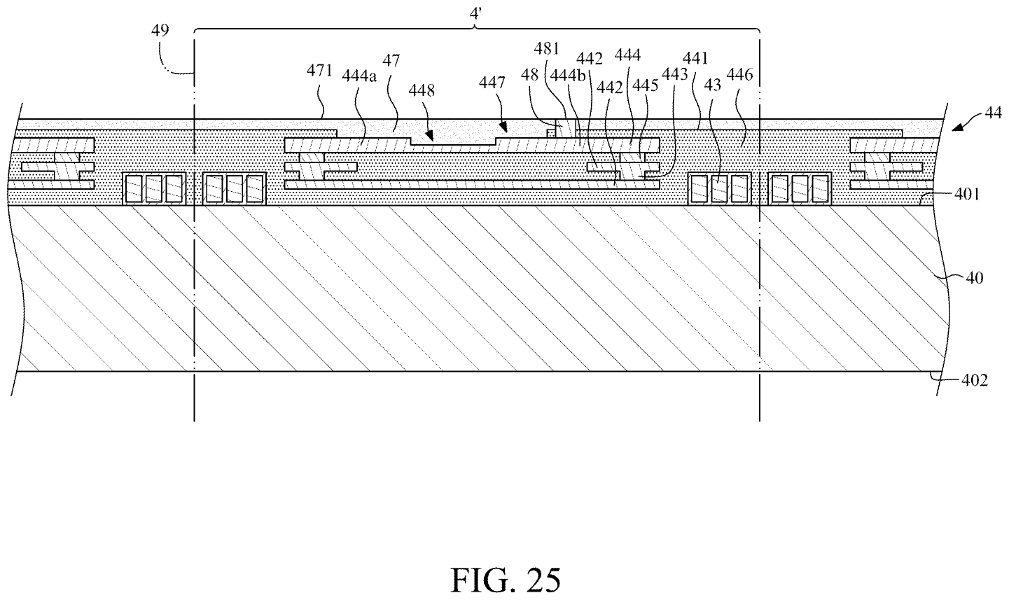

Referring to FIG. 25, a fourth top passivation layer 47 may be formed or disposed on the first surface 441 of the fourth conductive structure 44. The fourth top passivation layer 47 may cover the fourth opening 447. Then, a fourth connection via 48 may formed to extend through the fourth top passivation layer 47 and a portion of the dielectric structure 446 of the fourth conductive structure 44 on the fourth test pad 444 so as to electrically connect and physically connect to the second portion 444b of the fourth test pad 444. Then, a grinding process (e.g., chemical mechanical polishing (CMP)) may be conducted to a first surface 471 (e.g., top surface) of the fourth top passivation layer 47 such that a first surface 481 (e.g., a top surface) of the fourth connection via 48 may be substantially aligned with the first surface 471 of the fourth top passivation layer 47.

Then, the fourth substrate 40 and the fourth conductive structure 44 may be singulated along the singulation lines 49 as to form a plurality of fourth electronic devices 4 as shown in FIG. 5.

Then, the third electronic device 3 is stacked on or disposed on the fourth electronic device 4, the second electronic device 2 is stacked on or disposed on the third electronic device 3, and the first electronic device 1 is stacked on or disposed on the second electronic device 2. Thus, the first substrate 10 is stacked on the second conductive structure 24, the second substrate 20 is stacked on the third conductive structure 34, and the third substrate 30 is stacked on the fourth conductive structure 34. Thus, the first electronic device 1, the second electronic device 2, the third electronic device 3 and the fourth electronic device 4 are electrically connected to each other so as to form the electronic structure 5 of FIG. 1.

In some embodiments, the first electronic device 1, the second electronic device 2, the third electronic device 3 and the fourth electronic device 4 are connected to each other through hybrid bonding so as to form the electronic structure 5a of FIG. 7. As shown in FIG. 7, the first bottom passivation layer 16 and the second top passivation layer 27 may contact each other or may be fused together to form a first bonding layer 51. The second bottom passivation layer 26 and the third top passivation layer 37 may contact each other or may be fused together to form a second bonding layer 52. The third bottom passivation layer 36 and the fourth top passivation layer 47 may contact each other or may be fused together to form a third bonding layer 53. The first conductive via 15 and the second connection via 28 may contact each other or may be fused together to form a first interconnection pillar 54. The second conductive via 25 and the third connection via 38 may contact each other or may be fused together to form a second interconnection pillar 55. The third conductive via 35 and the fourth connection via 48 may contact each other or may be fused together to form a third interconnection pillar 56.

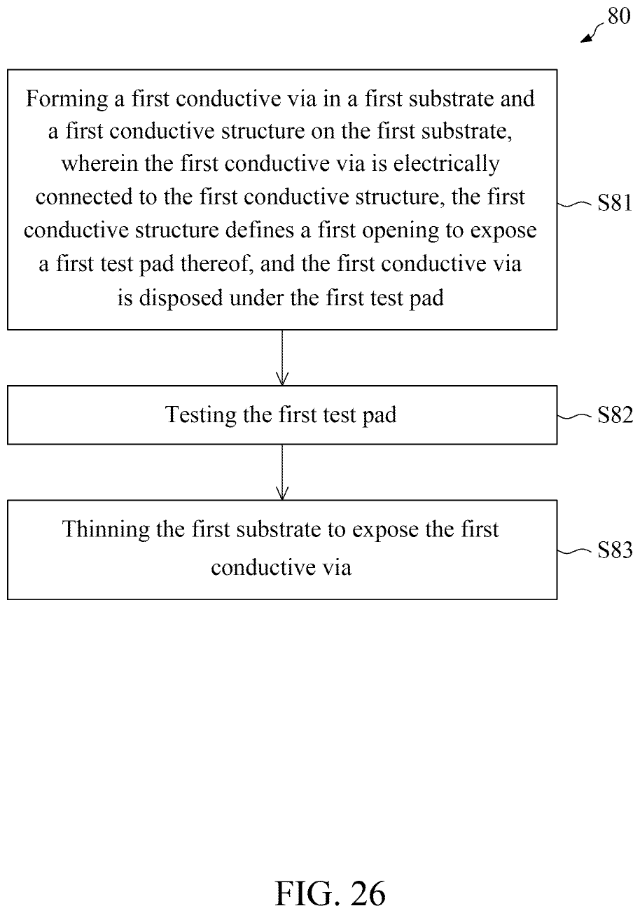

FIG. 26 illustrates a flow chart of a method 80 of manufacturing an electronic structure 5 in accordance with some embodiments of the present disclosure.

In some embodiments, the method 80 may include a step S81, forming a first conductive via in a first substrate and a first conductive structure on the first substrate, wherein the first conductive via is electrically connected to the first conductive structure, the first conductive structure defines a first opening to expose a first test pad thereof, and the first conductive via is disposed under the first test pad. For example, as shown in FIG. 16, a first conductive via 15 may be formed in a first substrate 10, and a first conductive structure 14 may be formed on the first substrate 10. The first conductive via 15 is electrically connected to the first conductive structure 14. The first conductive structure 14 defines a first opening 147 to expose a first test pad 144 thereof. The first conductive via 15 is disposed under the first test pad 144.

In some embodiments, the method 80 may include a step S82, testing the first test pad. For example, as shown in FIG. 16, the first test pad 144 is tested by using a probe 60.

In some embodiments, the method 80 may include a step S83, thinning the first substrate to expose the first conductive via. For example, as shown in FIG. 17, the first substrate 10 is thinned to expose the first conductive via 15.

One aspect of the present disclosure provides an electronic device including a substrate, a conductive structure and at least one external connector. The conductive structure is disposed on the substrate and includes a test pad configured to be contacted by a probe during a testing process. The external connector is electrically connected to the conductive structure and is exposed from a surface of the electronic device for an external electrical connection. A vertical projection of the at least one external connector overlaps a vertical projection of the test pad.

Another aspect of the present disclosure provides an electronic structure including a first substrate, a first conductive structure and a second conductive structure. The first conductive structure is disposed over the first substrate, and includes a first test pad configured to be contacted by a probe during a testing process. The second conductive structure is disposed under the first substrate, and includes a second test pad configured to be contacted by a probe during a testing process. An electrical path between the first conductive structure and the second conductive structure is located between the first test pad and the second test pad.

Another aspect of the present disclosure provides a manufacturing method. The manufacturing method includes forming a first conductive via in a first substrate and a first conductive structure on the first substrate, wherein the first conductive via is electrically connected to the first conductive structure, the first conductive structure defines a first opening to expose a first test pad thereof, and the first conductive via is disposed under the first test pad; testing the first test pad; and thinning the first substrate to expose the first conductive via.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, and composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. An electronic device, comprising:
a substrate;
a conductive structure disposed on the substrate and including a test pad configured to be contacted by a probe during a testing process; and
at least one external connector electrically connected to the conductive structure and exposed from a surface of the electronic device for an external electrical connection, wherein a vertical projection of the at least one external connector overlaps a vertical projection of the test pad.

2. The electronic device of claim 1, further comprising a capacitor disposed on the substrate.

3. The electronic device of claim 1, wherein the conductive structure further includes a plurality of patterned metal layers and a dielectric structure, wherein the test pad is electrically connected to the plurality of patterned metal layers, and the test pad and the plurality of patterned metal layers are embedded in the dielectric structure; the dielectric structure defines an opening to expose a first portion of the test pad configured to be contacted by the probe.

4. The electronic device of claim 3, wherein the first portion of the test pad has a probe mark thereon.

5. The electronic device of claim 3, wherein a vertical projection of the at least one external connector overlaps a vertical projection of the opening.

6. The electronic device of claim 3, wherein a vertical projection of the at least one external connector is located outside a vertical projection of the opening.

7. The electronic device of claim 1, wherein the at least one external connector includes a conductive via extending through the substrate and exposed from a bottom surface of the electronic device.

8. The electronic device of claim 7, further comprising a bottom passivation layer disposed on a bottom surface of the substrate and surrounding the conductive via, wherein a bottom surface of the bottom passivation layer is substantially aligned with a bottom surface of the conductive via.

9. The electronic device of claim 1, wherein the at least one external connector includes a connection via connected to a second portion of the test pad and exposed from a top surface of the electronic device.

10. The electronic device of claim 9, further comprising a top passivation layer disposed on a top surface of the conductive structure and surrounding the connection via, wherein a top surface of the top passivation layer is substantially aligned with a top surface of the connection via.

11. The electronic device of claim 1, wherein the at least one external connector includes a conductive via and a connection via, the conductive via extends through the substrate and is disposed under the conductive structure, the connection via extends through a portion of a dielectric structure of the conductive structure on the test pad, wherein the test pad is disposed between the conductive via and the connection via, and a width of the connection via is less than a width of the conductive via.

12. An electronic structure, comprising:
a first substrate;
a first conductive structure disposed over the first substrate and including a first test pad configured to be contacted by a probe during a testing process; and
a second conductive structure disposed under the first substrate and including a second test pad configured to be contacted by a probe during a testing process, wherein an electrical path between the first conductive structure and the second conductive structure is located between the first test pad and the second test pad.

13. The electronic structure of claim 12, wherein the electrical path includes a vertical electrical path, and a projection of the vertical electrical path on the second test pad is within a projection of the first test pad on the second test pad; the vertical electrical path passes through the first substrate.

14. The electronic structure of claim 12, further comprising an interconnection pillar electrically connecting the first conductive structure and the second conductive structure, wherein the interconnection pillar forms the electrical path, wherein the interconnection pillar includes a conductive via and a connection via, and a width of the connection via is less than a width of the conductive via, and the conductive via extends through the first substrate, and the connection via connects to the second test pad.

15. The electronic structure of claim 14, wherein the interconnection pillar includes a conductive via and a plurality of connection vias, and a width of each of the connection vias is less than a width of the conductive via.

16. The electronic structure of claim 12, further comprising a bonding layer bonding the first substrate and the second conductive structure, and the electrical path passes through the bonding layer, wherein the second conductive structure defines an opening to expose a portion of the second test pad, and the bonding layer extends into the opening to contact the portion of the second test pad.

17. A method for manufacturing an electronic device, comprising:
forming a first conductive via in a first substrate and a first conductive structure on the first substrate, wherein the first conductive via is electrically connected to the first conductive structure, the first conductive structure defines a first opening to expose a first test pad thereof, and the first conductive via is disposed under the first test pad;
testing the first test pad; and
thinning the first substrate to expose the first conductive via.

18. The method of claim 17, further comprising:
forming a first bottom passivation layer on a bottom surface of the first substrate to surround the first conductive via;
forming a second conductive structure on a second substrate, wherein the second conductive structure defines a second opening to expose a first portion of a second test pad thereof;
testing the second test pad;
forming a second connection via connected to a second portion of the second test pad; and
stacking the first substrate on the second conductive structure, wherein the first conductive via is connected to the second connection via.

19. The method of claim 18, further comprising:
forming a second top passivation layer on the second conductive structure, wherein the second top passivation layer covers the second opening, and the second connection via extends through the second top passivation layer.

20. The method of claim 19, further comprising:
forming a first bottom passivation layer on a bottom surface of the first substrate to surround the first conductive via,
wherein after stacking the first substrate on the second conductive structure, the first bottom passivation layer and the second top passivation layer are fused together to form a bonding layer bonding the first substrate and the second conductive structure.
